(19) United States
(12) Patent Application Publication
(10) Pub. No.: US 2007/0181286 A1
(43) Pub. Date: Aug. 9, 2007

(54) Structure for air conduction in radiator device

(76) Inventor: Jun-Qian Wang, Shen Yang (CN)

Correspondence Address: Molex Incorporated, 2222 Wellington Court, Lisle, IL, 60532, US

(21) Appl. No.: 10/582,448

(22) PCT Filed: Dec. 10, 2004
(86) PCT No.: PCT/US04/41672

§ 371 Date: Mar. 12, 2007

(30) Foreign Application Priority Data
Dec. 11, 2003 (CN) 200320123779.3

(51) Int. Cl. H05K 7/20

(52) U.S. Cl. 165/80.3; 165/121; 361/697

(57) ABSTRACT

A structure for a heat-dissipating device includes a radiator, a heat dissipating plate and a fan. The radiator has plurality of radiating fins, flow passages are formed between these radiating fins which are divided into middle part and two-side parts. The lower ends of the radiating fins in two-side parts each provides at least one passageway which is connected to some of the flow passages. A heat dissipating plate includes two opposing sides which provide notches relative to the passageway of the radiator respectively. The radiator is set on the heat dissipating plate which can be set on the heat-generating component. A fan is disposed over the radiator. The structure can channel partial airflow generated by the driving fans off the radiator with the two-side flow passages and the passageway of the radiator to flow to the other heat-generating components.

### FIELD OF THE INVENTION

The present invention relates to a heat dissipation device, and in particular, to a heat dissipation device that can be set on a heat-generating component to dissipate heat from that particular component while at the same time channeling partial airflow generated by the driving fans of the heat dissipation device to dissipate heat from other heat generating components.

### BACKGROUND OF THE INVENTION

With the rapid development of computer industry, the amount of heat being generated by heat generating components, such as microprocessor chips, is increasing while at the same time the size of these components is decreasing. In order to radiate the intensive heat to the environment to keep the heat generating components within their allowable operating temperatures, a large area heat dissipation device is placed on the heat-generating component to assist the heat dissipation.

The currently available stack radiators are made of metallic materials such as aluminum or copper with favorable heat conductivity, which have plurality of radiating fins interconnecting to form a fin group, so as to be set on the heat dissipating plate made of metallic materials with favorable heat conductivity. And then, the heat dissipating plate is set on the heat-generating component to assist the heat dissipation. In addition, a fan can also be set over the radiator, which can drive the cooling airflow from the top down to the radiating fins, so the hot airflow generated from the heat exchange is discharged from the two sides of the flow passages to assist in the heat dissipation.

However, the conventional radiator device can only assist in dissipating heat from a single heat-generating component. However, in computer systems, besides the main thermal source (the microprocessor chip), there is still secondary heat generating components. If we only arrange a radiator device just for dissipating heat from the microprocessor chip, the heat from the other heat generating components would also affect the radiating efficiency of the whole computer system. If we arrange radiator devices on each of the heat generating components that act as secondary heat sources, this would not only take up too much room but also make the production cost increase greatly. As such, the conventional heat dissipating device described above needs to be improved.

### SUMMARY OF THE INVENTION

The main purpose of the present invention is to provide a heat-dissipating device that is capable of dissipating heat from more than one heat-generating component. This device can channel partial airflow generated by the driving fans off the radiator through the two-side flow passages and the passageway of the radiator, and then the airflow flows to the other heat-generating components in order to assist the other heat-generating components in radiating and make a better radiating efficiency in the computer system. Furthermore, the other components that act as secondary heat sources do not need additional radiator devices, thus the structure would not take up additional room and the system production cost will decrease greatly.

In order to realize the said intention, a structure for air conduction in radiator device is provided, including: a radiator with plurality of radiating fins, flow passages are formed between these radiating fins which are divided into middle part and two-side parts. The lower ends of the radiating fins in two-side parts each provides at least one passageway which is connected to some of the flow passages; A heat dissipating plate, the two opposing sides of which provide notches relative to the passageway of the radiator respectively, the radiator is set on the heat dissipating plate which can be set on the heat-generating component; And a fan disposed over the radiator. The structure can channel partial airflow generated by the driving fans off the radiator with the two-side flow passages and the passageway of the radiator to flow to the other heat generating components.

The advantages of present invention are as follows: The structure for air conduction in radiator device can channel partial airflow generated by the driving fans off the radiator through the two-side flow passages and the passageway of the radiator to flow to the other heat-generating components, in order to assist the other heat-generating components in radiating and achieve a better radiating efficiency in the computer system. Furthermore, the other heat-generating components that act as secondary heat sources do not need an additional radiator device.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 is an exploded perspective view of the structure for air conduction in radiator device of the present invention.

FIG. 2 is a perspective assembly view (First) of the structure for air conduction in radiator device of the present invention.

FIG. 3 is a perspective assembly view (Second) of the structure for air conduction in radiator device of the present invention.

FIG. 4 is a front view of the structure for air conduction in radiator device of the present invention.

FIG. 5 is a bottom plan view of the structure for air conduction in radiator device of the present invention

FIG. 6 is a perspective view of the radiator and the frame of the present invention.

FIG. 7 is a top plan view of the radiator and the frame of the present invention.

FIG. 8 is a bottom plan of the radiator and the frame of the present invention.

### DETAILED DESCRIPTION OF THE PREFERRED EMBODIMENTS

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

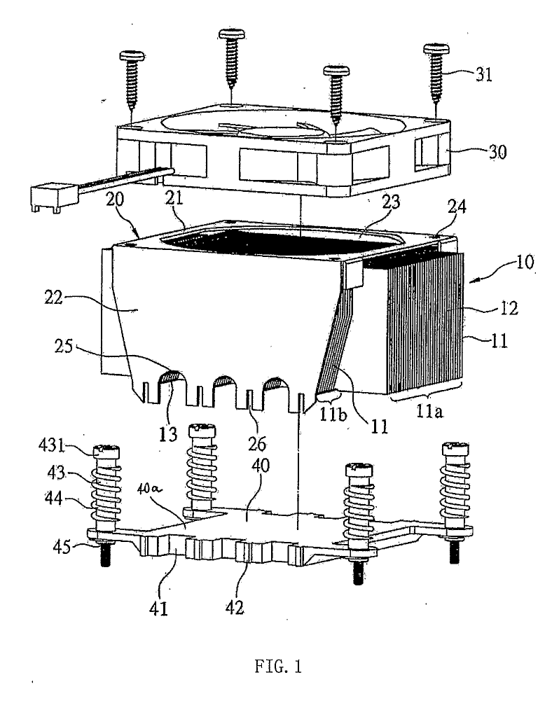

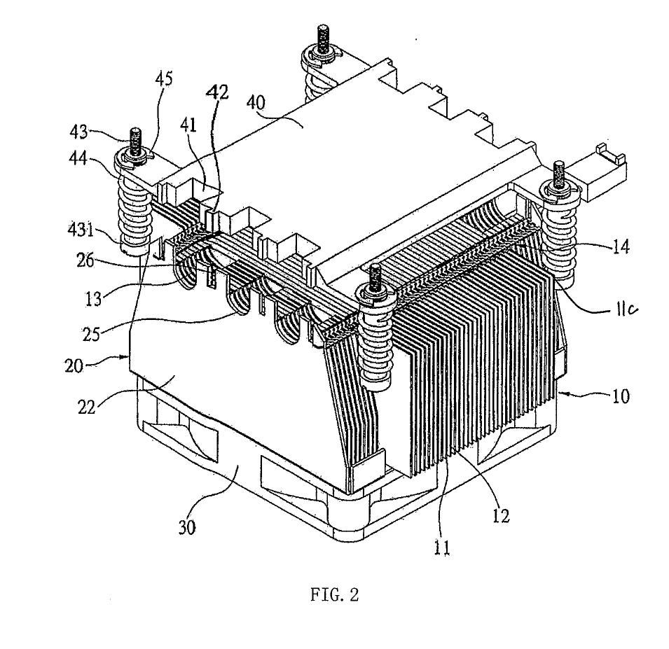

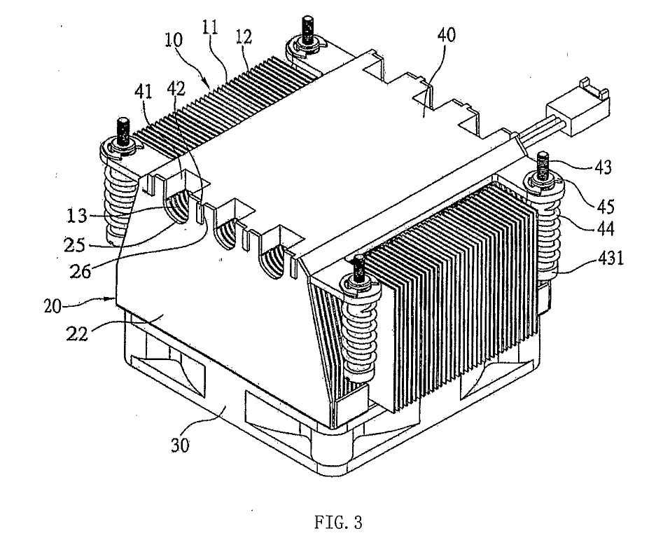

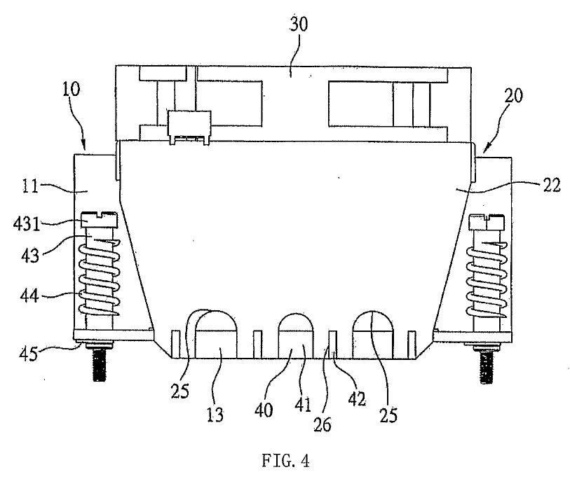

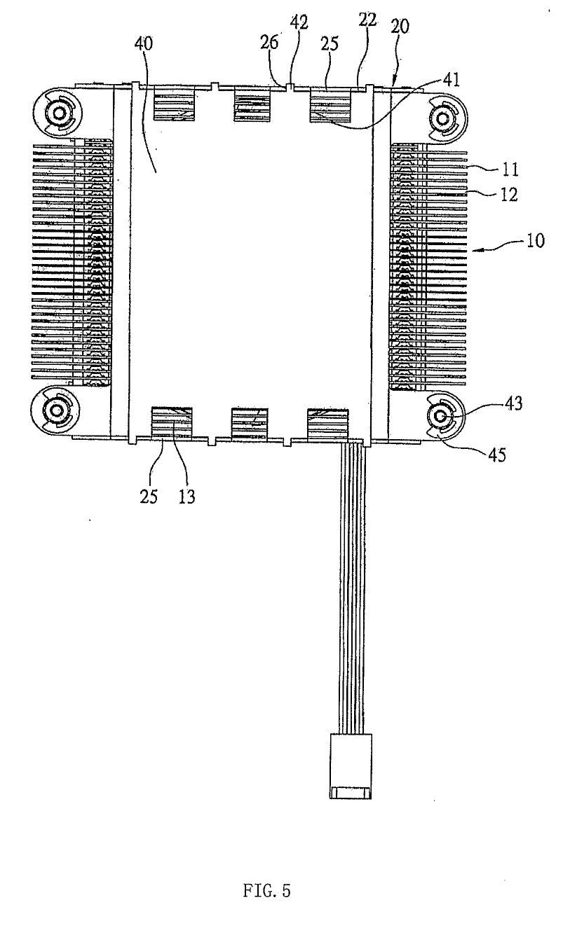

Referring to FIGS. 1 to 5, a heat dissipation device is disclosed, including a radiator 10, a frame 20, a fan 30 and a heat dissipating plate 40.

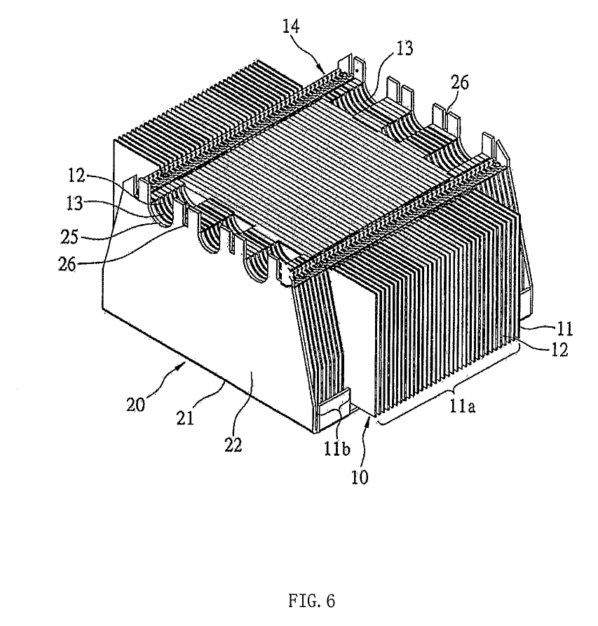

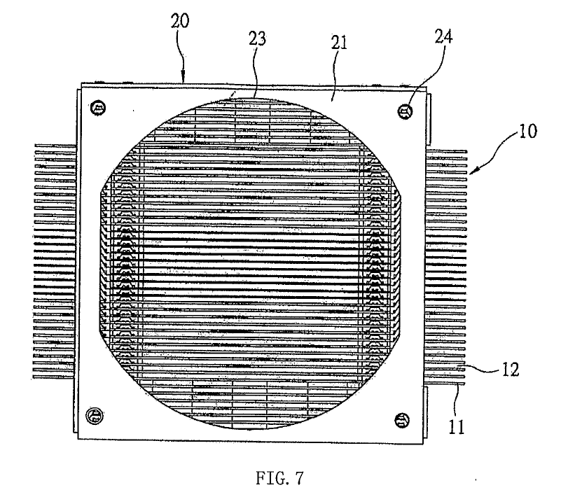

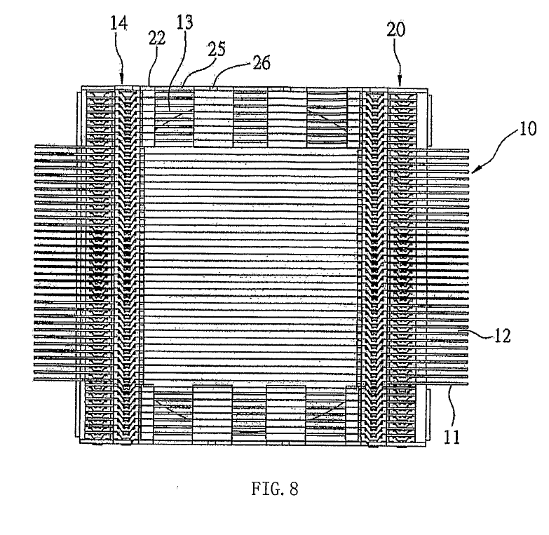

The radiators 10 are made of metallic materials such as aluminum or copper with favorable heat conductivity. The radiator has plurality of radiating fins 11 (Please refer to FIGS. 6 to 8). These radiating fins 11 are retained to each other by the use of a buckled clip connection 14 to form a fin group, and flow passages 12 are provided between these radiating fins 11 in order to pass the airflow through.

These radiating fins 11 can be further divided into a middle part 11a and two side parts 11b. The lower ends 11c of the radiating fins 11 in two side parts each provides at least one passageway 13 which are connected to some of the flow passages 12, and the direction of these passageways 13 is perpendicular to the direction of the flow passages 12.

The frame 20 is set on the top of the radiator 10 as well as two sides of it. The frame 20 has an upper plate 21 and two lateral plates 22 which are formed from the upper plate 21 extending correspondingly down to the two sides. The upper plate 21 has a through-hole 23, and the upper plate 21 provides four connection holes 24.

The fan 30 is arranged on the upper plate 21 corresponding to the through-hole 23. The fan 30 is screwed correspondingly to the four connection hole 24 using four screws 31 penetrating through the four corners of the fan 30 so that the fan 30 is fixed on the frame 20 and over the radiator 10 by screws.

The upper plate 21 and the two lateral plates 22 of the frame mount 20 are arranged for abutting the top and two sides of the radiator respectively. The lower ends 20a of the two lateral plates 22 each have openings 25 relative to the passageway 13, so that the passageways 13 can communicate outside of the heat dissipating device through the openings 25. The lower ends of the two lateral plates 22 also provide at least one groove 26 with an opening extending to the bottom of the plates. These grooves 26 are located between the openings 25.

The heat dissipating plate 40 is set under the radiator 10 and the frame 20, which is made of metallic materials such as aluminum or copper with favorable heat conductivity. The heat dissipating plate is generally planar. The two opposing sides of the heat dissipating plate 40 each have notches 41 corresponding to the openings 25 of the frame 20 and the passageways 13 of the radiator 10. The two opposing sides of the heat dissipating plate 40 also have corresponding flange ribs 42 to the grooves 26 of the frame 20. The flange ribs 42 are arranged between the notches 41.

The four corners of the heat dissipating plate 40 each have a screw bolt 43 arranged through therein. The lower ends of these screw-bolts 43 are screwed on the circuit board by penetrating through the bottom of the heat dissipating plate 40. Each of the screw-bolts 43 has a spring 44 hitched on it. The spring 44 are arranged between the head 431 of the screw-bolt 43 and the top 40a of the heat dissipating plate 40. Thus the heat dissipating plate 40 obtains an elastic downward force for the lower end of the spring 44 abutting against the top of the heat dissipating plate 40. In addition, these screw-bolts 43 each have a snap ring 45 buckled on it. The snap ring 45 is located under the heat dissipating plate 40 to prevent the screw-bolts 43 from disengaging the head dissipating plate 40.

The radiator 10 and the frame 20 are set on the heat dissipating plate 40 with the flange ribs 42 for the two sides of the heat dissipating plate 40 interacting with the grooves 26 in the lower ends of the two lateral plates 22 of the frame 20. These flange ribs 42 reciprocally connect to the grooves 26 so that the radiator 10 and the frame 20 can be fixed on the heat dissipating plate 40 firmly. By this connection, the structure of the heat conduction device of the present invention is formed.

The heat dissipating plate 40 is set on the heat-generating component and is fixed on the circuit board by the screw bolts 43 with elastic behavior to make the dissipating plate 40 press on the heat-generating component elastically. With the bottom of the heat dissipating plate 40 contacting to the heat-generating component, the heat generated from the heat-generating component is transferred to the radiator 10 by the heat dissipating plate 40.

Furthermore, with fans 30, the present invention can drive the cooling airflow to flow from the top down to the radiating fins 11 of the radiator 10, and vent the hot airflow generated from the heat exchange through the two sides of the flow passages 12, in order to assist the radiator 10 and the electronic heating element in radiating by the fans 30.

The present invention provides passageways 13 on the lower ends of the radiating fins 11 of the two side parts 11b of the radiator 10, the passageways 13 have the capability in air inducting. The frame 20 provides openings 25 that are corresponded to the notches 41 on the heat dissipating plate 40. Thus partial airflow generated from the driving fans 30 is channeled off the radiator through the flow passages 12 and the passageways 13 of two side parts 11b.

Because the radiating fins 11 only in middle part 11a of the radiator 10 is close to the central of the heat-generating component, the temperature is high, Yet the radiating fins 11 in the two sides parts 11b of the radiator 10 extend from the heat-generating component, the temperature is low. Thus the temperature of the airflow that channeled off the radiator through the flow passages 12 and the passageway 13 of two side parts 11b is low and can be recycled, namely to direct low temperature air from the passageways 13 to various other heat generating components that are not located directly below the heat dissipating plate (secondary heat sources). This allows for better overall system heat dissipation. Moreover, this additional heat dissipation is performed by a single heat dissipating device, thereby reducing the amount of room necessary to be used by the heat dissipating devices with the resultant decrease in overall system cost.

While a preferred embodiment of the present invention is shown and described, it is envisioned that those skilled in the art may devise various modifications of the present invention without departing from the spirit and scope of the appended claims.

What is claimed is:

1. A heat-dissipating device for dissipating heat from a heat-generating component, the heat dissipating device comprising:
a radiator, the radiator having a plurality of radiating fins, a flow passage being created between two adjacent radiating fins, wherein the fins are divided into a middle part and two side parts, the lower ends of the radiating fins in the two side parts providing at least one passageway, and the passageway are connected to some of the flow passages, the two opposing sides of a heat dissipating plate provide notches relative to the passageway of the radiator respectively;
a heat dissipating plate, the heat generating plate being located above the heat generating component and having two opposing sides, at least one of the sides of the heat dissipating plate providing notches that correspond to the radiator passageways; and
a fan, the fan being disposed on top of the radiator.

2. The heat-dissipating device according to claim 1, wherein the radiating fins is fitted together in stack mode and buckled together using a clip connection.

3. The heat dissipating device according to claim 1, wherein a frame is disposed on the radiator, the frame has an upper plate and two lateral plates set on the top and two sides of the radiator respectively, the two lateral plates having lower ends, the lower ends of the lateral plates each having openings relative to the passageway.

4. The heat dissipating device according to claim 3, wherein the lower ends of the two lateral plates of the frame provides at least one groove, the opposing two sides of the heat dissipating plate has flange ribs relative to the grooves of the lower ends of the two lateral plates of the frame, and wherein the flange ribs on the two side of the heat dissipating plate is inserted to connect to the grooves of the lower ends of the two lateral plates of the frame so that the radiator and frame are fixed on the heat dissipating plate.

5. The heat dissipating device according to claim 3, wherein the upper plate of the frame has a through-hole and wherein the fan is arranged on the upper plate corresponding to the through-hole.
